(19) United States
(12) Patent Application Publication
(10) Pub. No.: US 2007/0117414 A1
(43) Pub. Date: May 24, 2007

(54) METHODS AND APPARATUS FOR EPITAXIAL FILM FORMATION

(76) Inventors: Stephen Moffatt, St. Lawrence (GB); James Santiago, Boise, ID (US)

Correspondence Address: DUGAN & DUGAN, PC, 55 SOUTH BROADWAY, TARRYTOWN, NY, 10591, US

(21) Appl. No.: 11/538,195

(22) Filed: Oct. 3, 2006

Related U.S. Application Data
(60) Provisional application No. 60/723,675, filed on Oct. 5, 2005.

(51) Int. Cl. C30B 15/14; H01L 21/00

(52) U.S. Cl. 438/795; 117/3

(57) ABSTRACT

In a first aspect, a first system is provided for semiconductor device manufacturing. The first system includes (1) an epitaxial chamber adapted to form a material layer on a surface of a substrate; and (2) a plasma generator coupled to the epitaxial chamber and adapted to introduce plasma to the epitaxial chamber. Numerous other aspects are provided.

The present application claims priority to U.S. Provisional Patent Application Ser. No. 60/723,675, filed Oct. 5, 2005 and entitled “METHODS AND APPARATUS FOR EPITAXIAL FILM FORMATION,” (Attorney Docket No. 9759/L) which is hereby incorporated herein by reference in its entirety for all purposes.

### FIELD OF THE INVENTION

The present invention relates generally to semiconductor device manufacturing, and more particularly to methods and apparatus for epitaxial film formation.

### BACKGROUND

Some conventional methods of forming an epitaxial layer on a substrate may introduce contaminants to a surface of a substrate on which the epitaxial layer is formed. Further, temperatures associated with some conventional methods of forming an epitaxial layer on a substrate may be harmful to a semiconductor device formed thereon. Consequently, improved methods and apparatus for forming epitaxial layers are desired.

### SUMMARY OF THE INVENTION

In a first aspect of the invention, a first system is provided for semiconductor device manufacturing. The first system includes (1) an epitaxial chamber adapted to form an epitaxial layer on a surface of a substrate; and (2) a plasma generator coupled to the epitaxial chamber and adapted to introduce plasma to the epitaxial chamber.

In a second aspect of the invention, a first method is provided for semiconductor device manufacturing. The first method includes the steps of (1) providing a semiconductor device manufacturing system having (a) an epitaxial chamber adapted to form an epitaxial material layer on a surface of a substrate; and (b) a plasma generator coupled to the epitaxial chamber and adapted to introduce plasma to the epitaxial chamber; and (2) employing the semiconductor device manufacturing system to clean the surface of the substrate prior to forming the epitaxial material layer on the substrate.

In a third aspect of the invention, a second method is provided for semiconductor device manufacturing The second method includes the steps of (1) providing a semiconductor device manufacturing system having (a) an epitaxial chamber adapted to form an epitaxial material layer on a surface of a substrate; and (b) a plasma generator coupled to the epitaxial chamber and adapted to introduce plasma to the epitaxial chamber; and (2) employing the semiconductor device manufacturing system to form the epitaxial material layer on the substrate. Numerous other aspects are provided in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 is a block diagram of a semiconductor device manufacturing system including a plasma generator coupled to an epitaxial chamber in accordance with an embodiment of the present invention.

FIG. 2 is a block diagram of the semiconductor device manufacturing system of FIG. 1 including a high-temperature epitaxial chamber in accordance with an embodiment of the present invention.

FIG. 3 is a block diagram of the semiconductor device manufacturing system of FIG. 2 in which the high-temperature epitaxial chamber includes at least one heating module above and at least one heating module below a substrate support in accordance with an embodiment of the present invention.

FIG. 4 is a block diagram of the semiconductor device manufacturing system of FIG. 1 including a low-temperature epitaxial chamber in accordance with an embodiment of the present invention.

FIG. 5 is a block diagram of the semiconductor device manufacturing system of FIG. 4 in which the low-temperature epitaxial chamber includes a heating module below a substrate support in accordance with an embodiment of the present invention.

FIG. 6 illustrates a method of preparing a substrate surface for epitaxial film formation in accordance with an embodiment of the present invention.

FIG. 7 illustrates a method of epitaxial film formation in accordance with an embodiment of the present invention.

### DETAILED DESCRIPTION

The present invention provides methods and apparatus for manufacturing semiconductor devices. More specifically, the present invention provides a semiconductor device manufacturing system including an epitaxial chamber coupled to a plasma generator adapted to introduce plasma to the epitaxial chamber. Further, the present invention provides methods and apparatus for cleaning a surface of a substrate prior to forming an epitaxial layer on the substrate. Additionally, the present invention provides methods and apparatus for forming an epitaxial layer on the substrate.

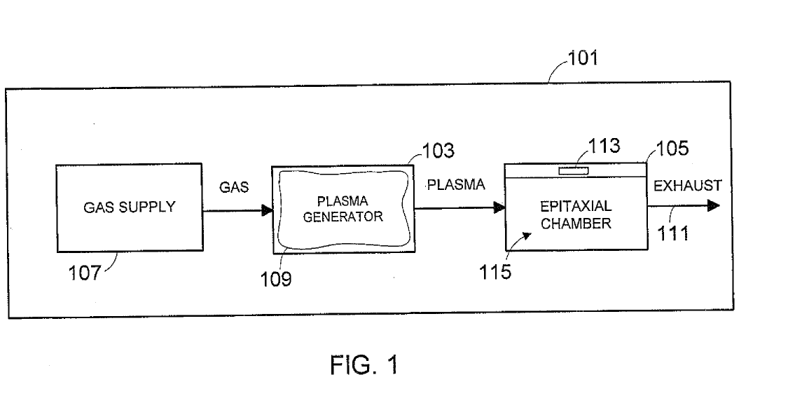

FIG. 1 is a block diagram of a semiconductor device manufacturing system 101 including a plasma generator 103 coupled to an epitaxial chamber 105 in accordance with an embodiment of the present invention. The plasma generator 103 may be adapted to introduce plasma to the epitaxial chamber 105. For example, the plasma generator 103 may include and/or be coupled to a microwave cavity (not shown). Further, the plasma generator 103 may include and/or be coupled to a microwave generator (not shown) coupled to the microwave cavity. The plasma generator 103 may receive a gas such as hydrogen or the like from a gas supply 107 and generate a plasma 109 based on the gas. The plasma 109 may be output from the plasma generator 103 into the epitaxial chamber 105.

In some embodiments, the plasma generator 103 may be a remote plasma generator or inductively coupled to the epitaxial chamber 105 although other configurations may be used. The plasma generator 103 may be adapted to create a plasma comprising ionized H₂ (e.g., H₂⁺) species, although a plasma comprising different species, ions and/or radicals may be employed. For example, deposition gases for use during epitaxial layer formation such as source gases, etchant gases, dopant gases, etc., also may be supplied from the plasma generator 103 (as described below) or otherwise supplied to the epitaxial chamber 105. In one or more embodiments, the plasma generator 103 may be adapted to produce a large area of plasma 109 having a uniform density, which may enable a substantially uniform epitaxial layer to be formed during subsequent processing.

The plasma generator 103 may be similar to the reaction chamber of U.S. Pat. No. 6,450,116, issued Sep. 17, 2002, entitled “Apparatus For Exposing a Substrate to Plasma Radicals”, which is hereby incorporated by reference herein in its entirety. However, a plasma generator 103 of a different configuration may be employed.

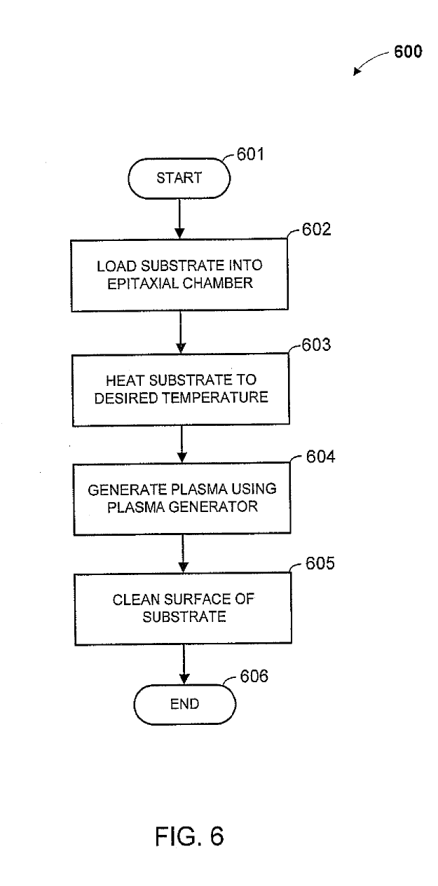

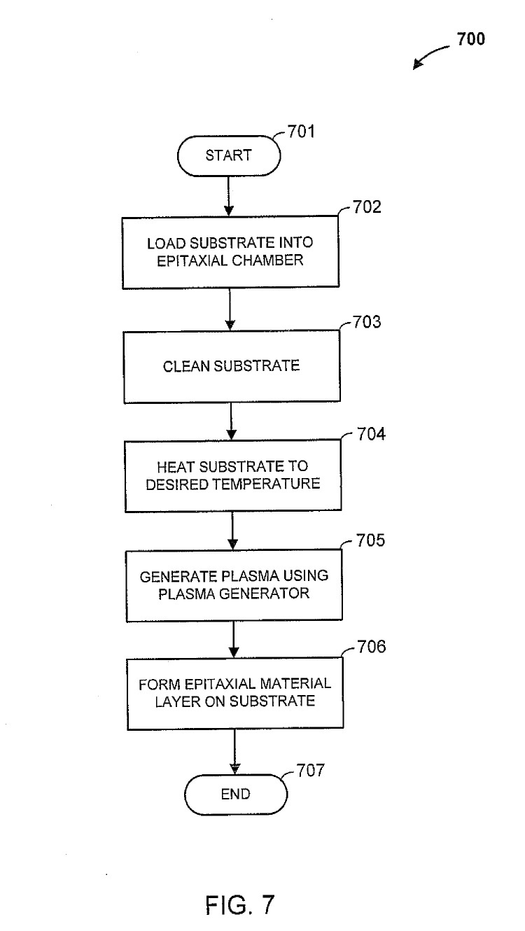

The epitaxial chamber 105 may be adapted to clean a surface of a substrate (not shown) included therein before forming an epitaxial layer on the substrate. For example, the epitaxial chamber 105 may expose the substrate (and plasma 109 introduced to the chamber 105) to a variety of process parameters (e.g., temperature, pressure, etc.) as described, for example, further below with reference to FIG. 6 such that a surface of the substrate may be cleaned. Further, the epitaxial chamber 105 may be adapted to form an epitaxial layer on the substrate (as described, for example, with reference to FIG. 7). The epitaxial chamber 105 may output unwanted gasses and/or byproducts via an exhaust or pump 111.

The epitaxial chamber 105 may include a plasma-exciting apparatus 113, such as one or more coils, positioned outside a vacuum portion 115 of the chamber 105 (e.g., in addition to or in place of the plasma generator 103). The plasma-exciting apparatus 113 may be formed from metal or another suitable material and the vacuum portion 115 of the chamber 105 may comprise quartz or another suitable material. Placing components of the plasma-exciting apparatus 113 (e.g., metal components) outside the vacuum portion 115 of the chamber 105 may prevent the components from contaminating the chamber 105 and/or any substrates processed with the chamber 105.

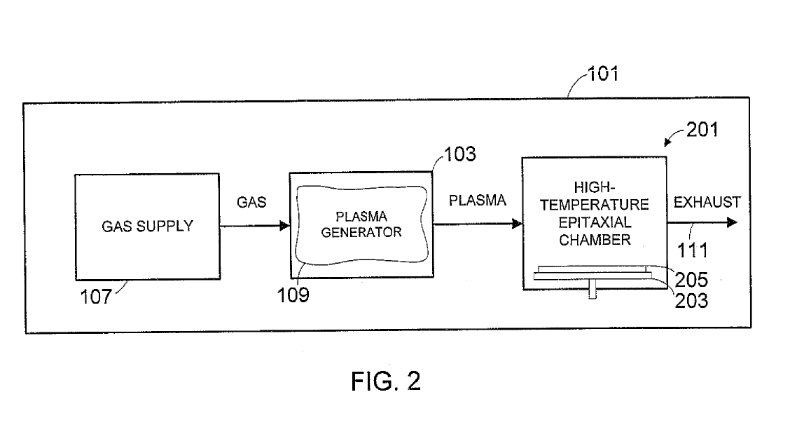

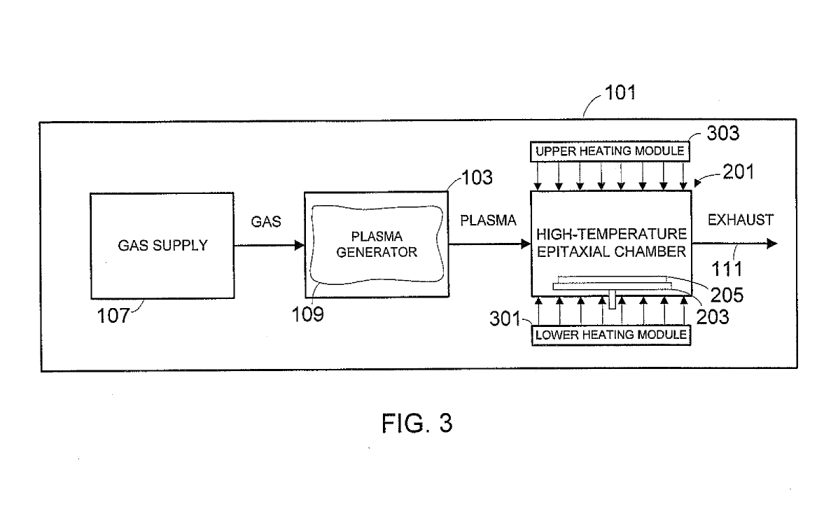

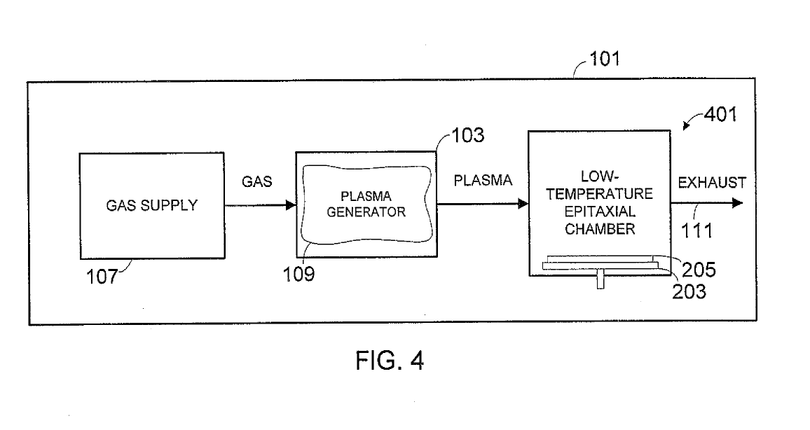

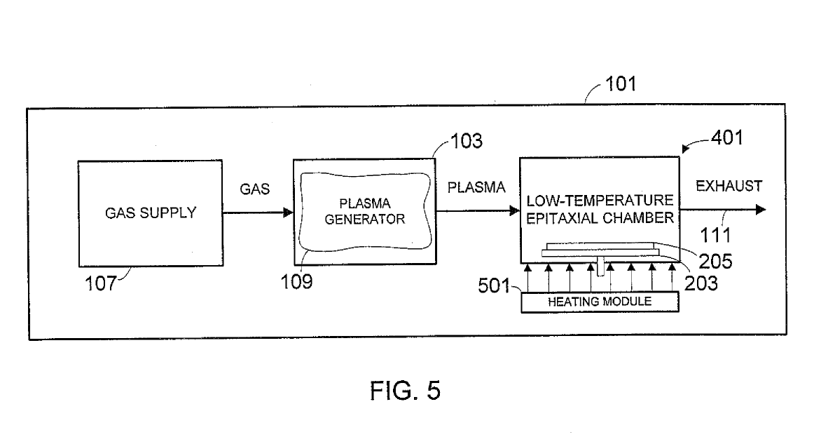

Details of a first exemplary epitaxial chamber 105 that may be included in the semiconductor device manufacturing system 101 are described below with reference to FIGS. 2-3 and details of a second exemplary epitaxial chamber 105 that may be included in the semiconductor device manufacturing system 101 are described below with reference to FIGS. 4-5.

FIG. 2 is a block diagram of the semiconductor device manufacturing system 101 of FIG. 1 including a high-temperature epitaxial chamber 201 in accordance with an embodiment of the present invention. With reference to FIG. 2, the high-temperature epitaxial chamber 201 may include a substrate holder 203 (e.g., susceptor) adapted to support a substrate 205. The high-temperature epitaxial chamber 201 may be adapted to receive plasma output from the plasma generator 103 and expose the plasma and the substrate 205 to a desired temperature such that a surface of the substrate 205 is cleaned.

FIG. 3 is a block diagram of the semiconductor device manufacturing system 101 of FIG. 2 in which the high-temperature epitaxial chamber 201 includes at least one lower heating module 301 (such as an infrared lamp or lamp array or another radiant heat source, only one shown) below the substrate holder 203 and at least one upper heating module 303 (such as an infrared lamp or lamp array or another radiant heat source, only one shown) above the substrate holder 203. The high-temperature epitaxial chamber 201 may employ the lower heating module 301 and upper heating module 303 to heat the substrate 205 to a desired temperature while exposing the substrate to a cleaning species such as a hydrogen plasma. In some embodiments, a substrate temperature of less than about 700° C., and more preferably between about 400° C. and 600° C. may be employed to clean the surface of the substrate 205 (although a larger or smaller and/or different temperature range may be employed). Use of ionized hydrogen species may reduce the temperature required to remove oxygen, organics, halogens and/or other contaminants from the substrate 205. Thereafter, an epitaxial layer may be formed on the clean surface of the substrate (as described below).

In some embodiments, the high-temperature epitaxial chamber 201 may be similar to the thermal reactor of U.S. Pat. No. 5,108,792, issued Apr. 28, 1992, entitled “Double-Dome Reactor For Semiconductor Processing”, which is hereby incorporated by reference herein in its entirety. However, a high-temperature epitaxial chamber 201 of a different configuration may be employed.

In contrast, FIG. 4 is a block diagram of the semiconductor device manufacturing system 101 of FIG. 1 including a low-temperature epitaxial chamber 401 in accordance with an embodiment of the present invention. With reference to FIG. 4, similar to the high-temperature epitaxial chamber 201, the low-temperature epitaxial chamber 401 may include the substrate holder 203 (e.g., susceptor) adapted to support substrate 205. The low-temperature epitaxial chamber 401 may be adapted to receive plasma output from the plasma generator 103 and expose the plasma and the substrate to a low temperature to clean a surface of the substrate 205. For example, FIG. 5 is a block diagram of the semiconductor device manufacturing system 101 of FIG. 4 in which the low-temperature epitaxial chamber 401 includes at least one heating module 501 positioned below the substrate support 203 in accordance with an embodiment of the present invention. The low-temperature epitaxial chamber 401 may employ the lower heating module 501 to heat the substrate 205 to a desired temperature while exposing the substrate 205 to a cleaning species such as a hydrogen plasma. In some embodiments, a substrate temperature of less than about 700° C., and more preferably between about 400° C. and 600° C. may be employed to clean the surface of the substrate 205 (although a larger or smaller and/or different temperature range may be employed). Use of ionized hydrogen species may reduce the temperature required to remove oxygen, organics, halogens and/or other contaminants from the substrate 205. Thereafter, an epitaxial layer may be formed on the clean surface of the substrate (as described below).

In some embodiments, the low-temperature epitaxial chamber 401 may be similar to the chamber of U.S. Pat. No. 6,455,814, issued Sep. 24, 2002, entitled “Backside Heating Chamber For Emissivity Independent Thermal Processes”, which is hereby incorporated by reference herein in its entirety. However, a low-temperature epitaxial chamber 401 of a different configuration may be employed.

The plasma generator 103 may be coupled (e.g., inductively) to any suitable chamber, such as a preclean chamber. For example, the plasma generator 103 may be coupled to an EpiClean chamber, which is manufactured by the assignee of the present application, Applied Materials, Inc. of Santa Clara, Calif. The EpiClean chamber may be adapted to heat a substrate from a lower side of the substrate. Further, the EpiClean chamber may be adapted to operate at pressures of less than about 5 Torr (e.g., by using a pump, such as a turbo pump). Alternatively, a semiconductor device manufacturing system including a remote plasma generator coupled to an epitaxial chamber may be employed. For example, a remote plasma generator may be coupled to the high-temperature epitaxial chamber 201, low-temperature epitaxial chamber 401, or the like.

An exemplary cleaning operation that may be performed within the semiconductor device manufacturing system 101 is now described with reference to FIG. 6 which illustrates a method 600 of preparing a substrate surface for epitaxial layer formation in accordance with an embodiment of the present invention. With reference to FIG. 6, in step 601, the method 600 begins. In step 602, a substrate is loaded into the epitaxial chamber 105 of the semiconductor device manufacturing system 101. In step 603, the substrate is heated to a desired temperature. For example, the substrate may be heated to a temperature of less than about 700° C., preferably about 400° C. to about 600° C. (although a larger or smaller and/or different temperature range may be employed). In step 604, the plasma generator 103 is employed to generate and supply a plasma to the epitaxial chamber 105. For example, a hydrogen plasma may be generated and supplied to the epitaxial chamber 105. Other reactive species may be similarly employed. Thereafter in step 605, the substrate is cleaned using the plasma. In this manner, a surface of the substrate may be cleaned (e.g., pre-cleaned) before additional processing, such as forming an epitaxial layer on the substrate, which may require a clean substrate surface. Use of ionized hydrogen species may reduce the temperature required to remove oxygen, organics, halogens and/or other contaminants from the substrate.

In step 606, the method 600 of FIG. 6 ends. Through use of the present methods and apparatus a surface of a substrate in an epitaxial chamber may be cleaned, preferably at a low temperature through use of a plasma. Consequently, contaminants may be removed from a surface of the substrate. In this manner, the present methods and apparatus may clean a substrate surface while avoiding high temperatures, which may adversely affect processing of semiconductor devices on the substrate. A method similar to the method 600 of FIG. 6 may be employed with a preclean chamber, such as an EpiClean chamber, which is manufactured by the assignee of the present application, Applied Materials, Inc. of Santa Clara, Calif.

FIG. 7 illustrates a method 700 of epitaxial film formation in accordance with an embodiment of the present invention. With reference to FIG. 7, in step 701, the method 700 begins. In step 702, a substrate is loaded into the epitaxial chamber 105 of the semiconductor device manufacturing system 101. In step 703, the substrate is cleaned. For example, the substrate may be cleaned using the method 600 of FIG. 6, or via any other known method. In step 704, the substrate is heated to a desired temperature. For example, the substrate may be heated to a temperature of between about 200° C. and 700° C., although other temperatures may be used. In step 705, a plasma is generated using the plasma generator 103. For example, a plasma that includes one or more of a carrier gas, etchant gas, silicon source, dopant source, and/or the like may be generated and supplied to the epitaxial chamber.

Exemplary source materials useful in the deposition gas to deposit silicon-containing compounds include silanes, halogenated silanes and organosilanes. Silanes include silane (SiH₄) and higher silanes with the empirical formula SiₓH₍₂ₓ₊₂₎, such as disilane (Si₂H₆), trisilane (Si₃H₈), and tetrasilane (Si₄H₁₀), as well as others. Halogenated silanes include compounds with the empirical formula X′_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂). Organosilane compounds have been found to be advantageous silicon sources as well as carbon sources in embodiments which incorporate carbon in the deposited silicon-containing compound. The preferred silicon sources include silane, dichlorosilane and disilane.

The deposition gas may contain at least a silicon source and a carrier gas, and may contain at least one secondary elemental source, such as a germanium source and/or a carbon source. Also, the deposition gas may further include a dopant compound to provide a source of a dopant, such as boron, arsenic, phosphorous, gallium and/or aluminum. In an alternative embodiment, the deposition gas may include at least one etchant, such as hydrogen chloride or chlorine.

Germanium sources useful to deposit silicon-containing compounds include germane (GeH₄), higher germanes and organogermanes. Higher germanes include compounds with the empirical formula GeₓH₍₂ₓ₊₂₎, such as digermane (Ge₂H₆), trigermane (Ge₃H₈) and tetragermane (Ge₄H₁₀), as well as others. organogermanes include compounds such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂).

Carbon sources useful to deposit silicon-containing compounds include organosilanes, alkyls, alkenes and alkynes of ethyl, propyl and butyl. Such carbon sources include methylsilane (CH₃SiH₃), dimethylsilane ((CH₃)₂SiH₂), ethylsilane (CH₃CH₂SiH₃), methane (CH₄), ethylene (C₂H₄), ethyne (C₂H₂) propane (C₃H₈), propene (C₃H₆), butyne (C₄H₆), as well as others.

Boron-containing dopants useful as a dopant source include boranes and organoboranes. Boranes include borane, diborane (B₂H₆), triborane, tetraborane and pentaborane, while alkylboranes include compounds with the empirical formula RₓBH₍₃₋ₓ₎, where R=methyl, ethyl, propyl or butyl and x=1, 2 or 3. Alkylboranes include trimethylborane ((CH₃)₃B), dimethylborane ((CH₃)₂BH), triethylborane ((CH₃CH₂)₃B) and diethylborane ((CH₃CH₂)₂BH). Dopants may also include arsine (AsH₃), phosphine (PH₃) and alkylphosphines, such as with the empirical formula RₓPH(₃₋ₓ₎, where R=methyl, ethyl, propyl or butyl and x=1, 2 or 3. Alkylphosphines include trimethylphosphine ((CH₃)₃P), dimethylphosphine ((CH₃)₂PH), triethylphosphine ((CH₃CH₂)₃P) and diethylphosphine ((CH₃CH₂)₂PH). Aluminum and gallium dopant sources may include alkylated and/or halogenated derivates, such as described with the empirical formula RₓMX₍₃₋ₓ₎, where M=Al or Ga, R=methyl, ethyl, propyl or butyl, X=Cl or F and x=0, 1, 2 or 3. Examples of aluminum and gallium dopant sources include trimethylaluminum (Me₃Al), triethylaluminum (Et₃Al), dimethylaluminumchloride (Me₂AlCl), aluminum chloride (AlCl₃), trimethylgallium (Me₃Ga), triethylgallium (Et₃Ga), dimethylgalliumchloride (Me₂GaCl) and gallium chloride (GaCl₃)

In step 706, an epitaxial layer is formed on the substrate. Different process and/or operational parameters may be employed based on chemistries employed to form the epitaxial layer. For example, the semiconductor device manufacturing system 101 may form an epitaxial layer of silicon, silicon germanium and/or another suitable semiconductor material on a surface of a substrate by using an RF-excited low-energy plasma at temperatures from about 200° C. to about 700° C. The semiconductor device manufacturing system 101 may excite the plasma inductively or by another suitable method using a source having a frequency of about 10 MHz to about 10 GHz (although a larger or smaller and/or different frequency range may be employed). In some embodiments, the semiconductor device manufacturing system 101 may be adapted such that an electron kinetic energy of the plasma is less than about 15 V (although a larger or smaller and/or different kinetic energy range may be employed).

In step 707, the method 700 of FIG. 7 ends. Through use of the present methods and apparatus an epitaxial layer may be formed on a surface of a substrate using a low-energy plasma. When an RF plasma is employed in accordance with the present invention, use of the RF plasma may avoid substrate contamination by metal components associated with convention DC plasma systems. The present methods and apparatus may be employed to create silicon-on-insulator substrates and/or substrates employed for optical applications. Further, because the present methods and apparatus employ plasma to form (e.g., dissociate and deposit) an epitaxial layer of one or more materials on a substrate rather than a thermal source, the epitaxial layer may be formed using a lower temperature.

Through use of the present invention, a wide pressure range may be employed for epitaxial layer formation. Different plasma frequencies may be used for different chemistries, and a large area uniform density plasma may be formed (e.g., for uniform deposition).

The foregoing description discloses only exemplary embodiments of the invention. Modifications of the above disclosed apparatus and methods which fall within the scope of the invention will be readily apparent to those of ordinary skill in the art. For instance, in the embodiments above, each high-temperature epitaxial chamber includes at least one lower heating module 301 below the substrate holder 203 and/or at least one upper heating module 303 above the substrate holder 203. Any number of such heating modules may be employed.

Accordingly, while the present invention has been disclosed in connection with exemplary embodiments thereof, it should be understood that other embodiments may fall within the spirit and scope of the invention, as defined by the following claims.

The invention claimed is:

1. A semiconductor device manufacturing system, comprising:
an epitaxial chamber adapted to form a material layer on a surface of a substrate; and
a plasma generator coupled to the epitaxial chamber and adapted to introduce plasma to the epitaxial chamber.

2. The semiconductor device manufacturing system of claim 1 wherein the plasma generator is adapted to provide a plasma that cleans a surface of the substrate before the epitaxial chamber forms an epitaxial layer on the substrate.

3. The semiconductor device manufacturing system of claim 1 wherein the plasma generator is remote from the epitaxial chamber.

4. The semiconductor device manufacturing system of claim 1 wherein the plasma generator is inductively coupled to the epitaxial chamber.

5. The semiconductor device manufacturing system of claim 1 wherein the epitaxial chamber includes a plasma-exciting apparatus positioned outside a vacuum portion of the epitaxial chamber.

6. The semiconductor device manufacturing system of claim 5 wherein the plasma-exciting apparatus includes one or more coils.

7. The semiconductor device manufacturing system of claim 1 wherein the epitaxial chamber is adapted to heat the substrate to a temperature of less than about 700° C. during at least one of substrate cleaning and epitaxial film formation.

8. The semiconductor device manufacturing system of claim 7 wherein the epitaxial chamber includes:
at least one lower substrate heating module below a substrate holder of the epitaxial chamber; and
at least one upper substrate heating module above the substrate holder of the epitaxial chamber.

9. The semiconductor device manufacturing system of claim 8 wherein each heating module includes a radiant heat source.

10. The semiconductor device manufacturing system of claim 1 wherein the epitaxial chamber is adapted to heat the substrate to a temperature between about 400° C. and 600° C. during at least one of substrate cleaning and epitaxial film formation.

11. The semiconductor device manufacturing system of claim 10 wherein the epitaxial chamber further comprises at least one substrate heating module positioned below the substrate support.

12. A method of semiconductor device manufacturing, comprising:
providing a semiconductor device manufacturing system having:
an epitaxial chamber adapted to form an epitaxial material layer on a surface of a substrate; and
a plasma generator coupled to the epitaxial chamber and adapted to introduce plasma to the epitaxial chamber; and
employing the semiconductor device manufacturing system to clean the surface of the substrate prior to forming the epitaxial material layer on the substrate.

13. The method of claim 12 wherein employing the semiconductor device manufacturing system to clean the surface of the substrate prior to forming the epitaxial layer on the substrate includes:
employing the epitaxial chamber to heat the substrate to a temperature of less than about 700° C.;
employing the plasma generator to generate and supply a plasma to the epitaxial chamber; and
cleaning the substrate using the plasma.

14. The method of claim 13 wherein employing the epitaxial chamber to heat the substrate to a temperature of less than about 700° C. includes employing the epitaxial chamber to heat the substrate to a temperature between about 400° C. and 600° C.

15. The method of claim 12 further comprising employing the epitaxial chamber to form an epitaxial layer on the substrate.

16. The method of claim 15 wherein employing the epitaxial chamber to form an epitaxial layer on the substrate comprises using a plasma to dissociate species used during epitaxial layer formation.

17. A method of semiconductor device manufacturing, comprising:
providing a semiconductor device manufacturing system having:
an epitaxial chamber adapted to form an epitaxial material layer on a surface of a substrate; and
a plasma generator coupled to the epitaxial chamber and adapted to introduce plasma to the epitaxial chamber; and
employing the semiconductor device manufacturing system to form the epitaxial material layer on the substrate.

18. The method of claim 17 further comprising employing the semiconductor device manufacturing system to clean a surface of the substrate prior to forming the epitaxial material layer on the substrate.

19. The method of claim 17 wherein employing the semiconductor device manufacturing system to form the epitaxial material layer on the substrate includes:
employing the epitaxial chamber to heat the substrate to a temperature of less than about 700° C.;
employing the plasma generator to generate plasma; and
forming the epitaxial material layer using the plasma.

20. The method of claim 19 wherein employing the epitaxial chamber to heat the substrate to a temperature of less than about 700° C. includes employing the epitaxial chamber to heat the substrate to a temperature between about 400° C. and 600° C.

21. The method of claim 19 wherein employing the plasma generator to generate plasma includes exciting the plasma using RF energy.

22. The method of claim 21 wherein exciting the plasma using RF energy includes employing a power source having a frequency of about 10 MHz to about 10 GHz.

23. The method of claim 21 wherein employing the plasma generator to generate plasma includes employing the plasma generator to generate plasma having a kinetic energy of less than about 15 volts.
